(19) United States
(12) Patent Application Publication
(10) Pub. No.: US 2025/0374808 A1
(43) Pub. Date: Dec. 4, 2025

(54) DISPLAY PANEL AND DISPLAY DEVICE

(71) Applicant: Xiamen Tianma Display Technology Co., Ltd., Xiamen (CN)

(72) Inventor: Yongxiang LIN, Xiamen (CN)

(21) Appl. No.: 19/169,747

(22) Filed: Apr. 3, 2025

(30) Foreign Application Priority Data
May 28, 2024 (CN) 202410674759.1

(51) Int. Cl. H10K 59/80

(52) U.S. Cl. CPC H10K 59/874

(57) ABSTRACT

A display panel and a display device are provided. The display panel includes a display area and a non-display area. The non-display area includes an inorganic layer area; the inorganic layer area is adjacent to the display area; the inorganic layer area is formed with a groove; and a filler is formed in the groove.

### CROSS-REFERENCE TO RELATED APPLICATION

This application claims the priority of Chinese Patent Application No. 202410674759.1, filed on May 28, 2024, the content of which is incorporated by reference in its entirety.

### TECHNICAL FIELD

The present disclosure generally relates to the field of display technologies and, more particularly, relates to a display panel and a display device.

### BACKGROUND

Organic light-emitting diode (OLED) has the characteristic of self-emitting, and does not require an additional light source, which is conducive to the overall thinness of the display device. Further, organic self-emitting display technology also has the characteristics of fast response speed, wide viewing angle, high brightness, and low power consumption, becoming the focus of current research. Fabricating organic light-emitting diodes on a flexible substrate can also realize the production of flexible display devices. At present, OLED display panels have the problem of light-emitting at the edge of the display area. The present disclosed display panels and display devices are direct to solve such a problem and other problems in the arts.

### SUMMARY

One aspect of the present disclosure provides a display panel. The display panel includes a display area and a non-display area. The non-display area includes an inorganic layer area; the inorganic layer area is adjacent to the display area; the inorganic layer area is formed with a groove; and a filler is formed in the groove.

Another aspect of the present disclosure includes a display device. The display device includes a display panel. The display panel includes a display area and a non-display area. The non-display area includes an inorganic layer area; the inorganic layer area is adjacent to the display area; the inorganic layer area is formed with a groove; and a filler is formed in the groove.

Other aspects of the present disclosure can be understood by those skilled in the art in light of the description, the claims, and the drawings of the present disclosure.

### BRIEF DESCRIPTION OF THE DRAWINGS

To illustrate the technical solutions in the embodiments of the present disclosure more clearly, the following briefly introduces the accompanying drawings used in the description of the embodiments. Obviously, the accompanying drawings in the following description are only some embodiments of the present disclosure, for those of ordinary skill in the art, other drawings can also be obtained from these drawings without creative effort.

FIG. 1 illustrates a partial cross-sectional view of a display panel;

FIG. 2 illustrates a top view of an exemplary display panel according to various disclosed embodiments of the present disclosure;

FIG. 3 illustrates an A-A′-sectional view of the display panel in FIG. 2;

FIG. 4 illustrates another A-A′-sectional view of the display panel in FIG. 2;

FIG. 5 illustrates another A-A′-sectional view of the display panel in FIG. 2;

FIG. 6 illustrates a top view of another exemplary display panel according to various disclosed embodiments of the present disclosure;

FIG. 7 illustrates a top view of another exemplary display panel according to various disclosed embodiments of the present disclosure;

FIG. 8 illustrates a top view of another exemplary display panel according to various disclosed embodiments of the present disclosure;

FIG. 9 illustrates a top view of another exemplary display panel according to various disclosed embodiments of the present disclosure;

FIG. 10 illustrates a top view of another exemplary display panel according to various disclosed embodiments of the present disclosure;

FIG. 11 illustrates a top view of another exemplary display panel according to various disclosed embodiments of the present disclosure;

FIG. 12 illustrates a top view of another exemplary display panel according to various disclosed embodiments of the present disclosure;

FIG. 13 illustrates a B-B′-sectional view of the display panel in FIG. 12; and

FIG. 14 illustrates an exemplary display device according to various disclosed embodiments of the present disclosure.

### DETAILED DESCRIPTION

To more clearly understand the above-mentioned purpose, features and advantages of the present disclosure, the scheme of the present disclosure will be further described below. It should be noted that, in the absence of conflict, the embodiments of the present disclosure and the technical features in the embodiments can be combined with each other.

In the following description, many specific details are explained to facilitate a full understanding of the present disclosure, but the disclosure may also be implemented in other ways different from those described herein; obviously, the embodiments in the specification are only part of the embodiments of the disclosure, not all of the embodiments.

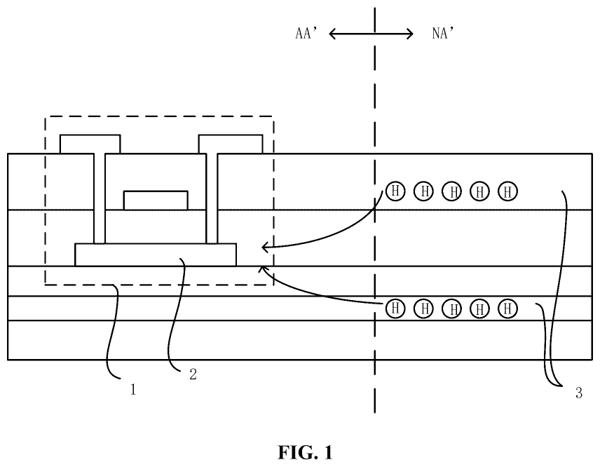

FIG. 1 is a partial cross-sectional schematic diagram of a display panel. As shown in FIG. 1, the display panel includes a multi-layer insulation layer 3, and the insulation layer 3 is arranged between two metal layers such that the insulation layer 3 plays an insulating role. The material of the insulation layer 3 is silicon nitride, and there are usually more hydrogen elements in the insulation layer 3. Since there are fewer vias on the side of the non-display area NA′ adjacent to the display area AA′, the hydrogen elements cannot be eliminated, resulting in more hydrogen elements gathering in this area, and the hydrogen elements will move to the edge of the display area AA′. Accordingly, the hydrogen elements will move to the active layer 2 in the transistor 1 at the edge of the display area AA′. In some aspects, hydrogen degrades the electrical characteristics of the active layer 2 by reacting with the active layer 2, thereby affecting the characteristics of the transistor 1 at the edge of the display area AA′, resulting in the problem of the display panel having a bright edge of the display area.

In view of the above technical problems, the present disclosure provides a display panel and a display device, which may effectively alleviate the phenomenon that the edge of the display area in the display panel is prone to brightening.

The display panel and the display device provided by the embodiments of the present disclosure are exemplarily described below in conjunction with the accompanying drawings.

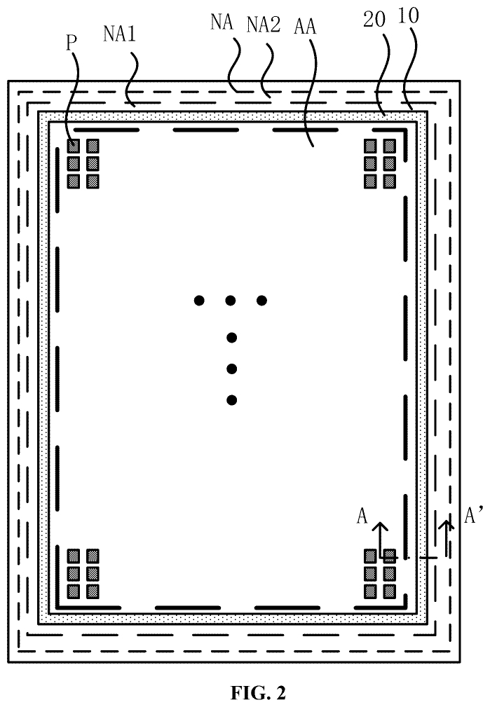

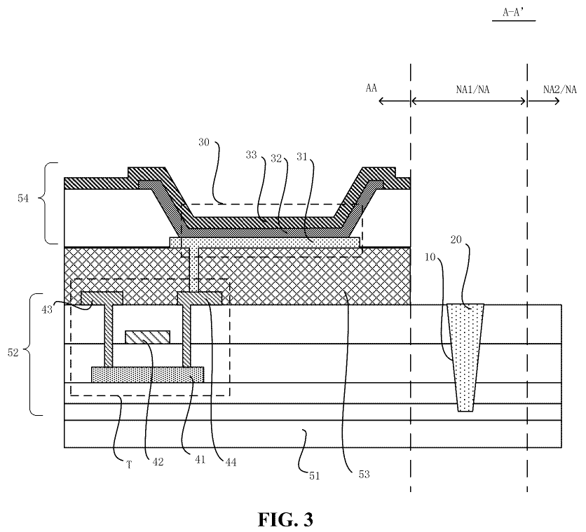

FIG. 2 is a top-view schematic diagram of an exemplary display panel according to various disclosed embodiments of the present disclosure. FIG. 3 is an A-A′-sectional view of the display panel described in FIG. 2. As shown in FIGS. 2-3, the display panel may include a display area AA and a non-display area NA. The non-display area NA may include an inorganic layer area NA1, and the inorganic layer area NA1 may be adjacent to the display area AA. The inorganic layer area NA1 may be formed with a groove 10, and a filler 20 may be formed in the groove 10.

Specifically, the display panel may include a display area AA and a non-display area NA at least partially surrounding the display area AA. In one embodiment, the non-display area NA may only partially surround the display area AA. In another embodiment, the non-display area NA may be arranged around the entire display area AA. This disclosure does not specifically limit the setting shape of the non-display area NA. The non-display area NA may be a closed ring shape surrounding the display area AA, for example, the non-display area NA may be arranged entirely around the display area AA (as shown in FIG. 2). The non-display area NA may also be an unclosed arc shape surrounding the display area AA (not shown in the figure in this embodiment), for example, the non-display area NA may also be arranged only around a portion of the display area AA. When it is implemented, it may be designed according to actual needs.

The display area AA may be used for display, including a plurality of sub-pixel units P. The non-display area NA may not be used for display, but may be used to set circuits and other structures.

In one embodiment, the display panel may be an organic light-emitting display panel, and the display panel may include a base substrate 51, a driving circuit layer 52, a planarization layer 53, a light-emitting device layer 54, a thin-film encapsulation layer (not shown in the figure) and other film layers arranged on the base substrate 51. FIG. 3 is only a simple schematic diagram of the film layer structure of the display panel. This embodiment does not repeat the specific film layer structure of the display panel, and details may be referred to the design structure of the organic light-emitting display panel in the relevant technology. Among them, the display area AA may include a plurality of sub-pixel units P, and a sub-pixel unit P may include a light-emitting element 30 and a driving circuit for driving the light-emitting element 30 to emit light. The driving circuit may include a plurality of transistors T, and the transistor T may include a gate 42, an active layer 41, a source 43, and a drain 44. The display principle of the organic light-emitting display panel may include that the anode 31 and the cathode 33 of the light-emitting element 30 are driven by a certain electric field, and the electrons and holes are respectively injected from the cathode 33 and the anode 31 into the electron and hole transport layers, and the electrons and holes respectively migrate to the light-emitting layer 32 of the light-emitting element 30 through the electron and hole transport layers, and meet in the light-emitting layer 32 to form excitons and excite the light-emitting molecules. When the power is supplied to an appropriate voltage, the holes in the anode 31 and the charges in the cathode 33 may combine in the light-emitting layer 32 to generate light, and the three primary colors of red, green and blue are generated according to their different formulas to form basic colors and form a display screen. In one embodiment, the display area AA of the display panel may include multiple sub-pixel units P of different colors.

It should be noted that this embodiment exemplarily shows that the display panel is an organic light-emitting display panel. In other embodiments of the present disclosure, the display panel may also be a liquid crystal display panel or other types of display panels, which will not be repeated in the present disclosure.

The non-display area NA may include an inorganic layer area NA1, and the inorganic layer area NA1 may include multiple inorganic layers such as a buffer layer, a gate insulation layer, an interlayer insulation layer, and a passivation layer. The material of the inorganic layer may be an inorganic material, such as silicon oxide, silicon nitride, silicon oxynitride, aluminum oxide or aluminum nitride, etc. The inorganic layer area NA1 may be adjacent to the display area AA, and a groove 10 may be formed in the inorganic layer area NA1. The setting of the groove 10 may effectively block the hydrogen element in the inorganic layer area NA1 from moving to the display area AA, thereby preventing the hydrogen element from moving to the active layer 41 of the transistor T in the display area AA, thereby effectively preventing the hydrogen element from reacting with the active layer 41 to deteriorate the electrical characteristics of the active layer 41. Accordingly, the stability of the characteristics of the transistor T at the edge of the display area AA may be effectively improved, and the problem of the display panel having a bright edge of the display area AA may be effectively alleviated.

A filler 20 may be formed in the groove 10. The material of the filler 20 may be a material that attracts hydrogen elements such that the filler 20 may attract hydrogen elements in the inorganic layer area NA1, which may be conducive to the discharge of hydrogen elements from the display panel through the filler 20, effectively reducing the hydrogen elements in the inorganic layer area NA1, and thereby effectively preventing the hydrogen elements from moving to the active layer 41 of the transistor T in the display area AA. Accordingly, the hydrogen elements may effectively be prevented from reacting with the active layer 41 to degrade the electrical characteristics of the active layer 41, the stability of the characteristics of the transistor T at the edge of the display area AA may effectively be improved and the problem of the display panel having a bright edge of the display area AA may be alleviated.

Further, referring to FIG. 2 and FIG. 3, in some embodiments, the filler 20 may be a metal film layer or an organic film layer. Specifically, when the material of the filler 20 is a metal layer, the filler 20 may play a role in attracting hydrogen elements in the inorganic layer area NA1, thereby facilitating the discharge of hydrogen elements from the display panel through the filler 20, effectively reducing the hydrogen elements in the inorganic layer area NA1, and thereby effectively preventing the hydrogen elements from moving to the active layer 41 of the transistor T in the display area AA, and thereby effectively preventing the hydrogen elements from reacting with the active layer 41 to degrade the electrical characteristics of the active layer 41. Accordingly, the stability of the characteristics of the transistor T at the edge of the display area AA may effectively be improved, thereby alleviating the problem of the display panel having a bright edge of the display area AA.

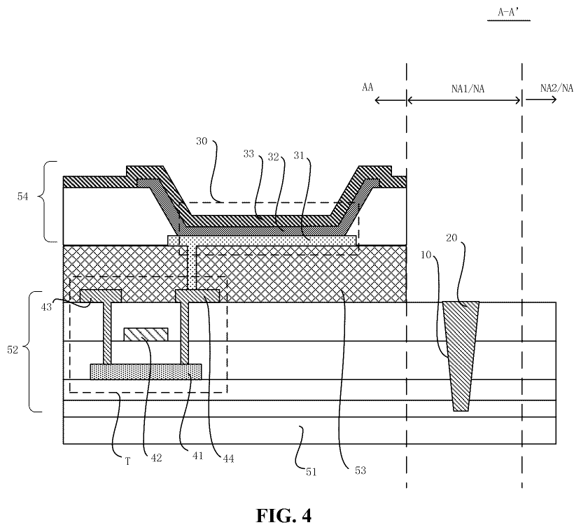

FIG. 4 is another cross-sectional view of the display panel along A-A′ described in FIG. 2. Referring to FIG. 2 and FIG. 4, in one embodiment, the material of the filler 20 may be same as that of the source 43 and the drain 44 in the transistor T. For example, the filler 20 may be made of the same material and in the same process as the source 43 and the drain 44 in the transistor T. While realizing that the material of the filler 20 is metal, the process may be effectively reduced, and the production cost may be reduced.

It should be noted that, this embodiment exemplarily shows that when the material of the filler 20 is a metal material, it may be made in the same process as the source 43 and the drain 44 in the transistor T using the same material. In other embodiments of the present disclosure, the filler 20 may also be made of other metal film layers in the display panel, which will not be described in detail in the present disclosure.

When the material of the filler 20 is an organic material, the filler 20 may play a role in attracting the hydrogen elements in the inorganic layer area NA1, thereby facilitating the discharge of the hydrogen elements from the display panel through the filler 20, effectively reducing the hydrogen elements in the inorganic layer area NA1, and thereby effectively preventing the hydrogen elements from moving to the active layer 41 of the transistor T in the display area AA. Accordingly, the hydrogen elements may be effectively prevented from reacting with the active layer 41 to degrade the electrical characteristics of the active layer 41, effectively improving the stability of the characteristics of the transistor T at the edge of the display area AA, and thereby alleviating the problem of the display panel having a bright edge of the display area AA.

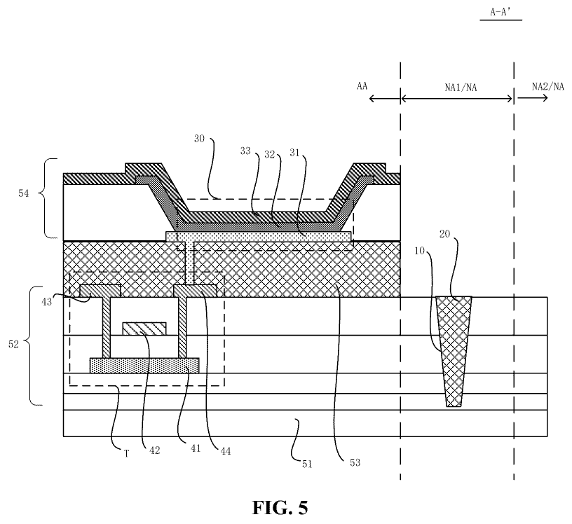

FIG. 5 is another exemplary cross-sectional view of the display panel along A-A′ described in FIG. 2. Referring to FIG. 2 and FIG. 5, in one embodiment, the material of the filler 20 may be same as the material of the planarization layer 53. For example, the filler 20 may be made of a same material as the planarization layer 53 in the same process. While the material of the filler 20 is an organic material, the process may be effectively reduced and the production cost may be reduced.

It should be noted that this embodiment exemplarily shows that when the material of the filler 20 is an organic material, it may be made of the same material as the planarization layer 53 in the same process. In other embodiments of the present disclosure, the filler 20 may also be made of other organic film layers in the display panel, which will not be described in detail in the present invention.

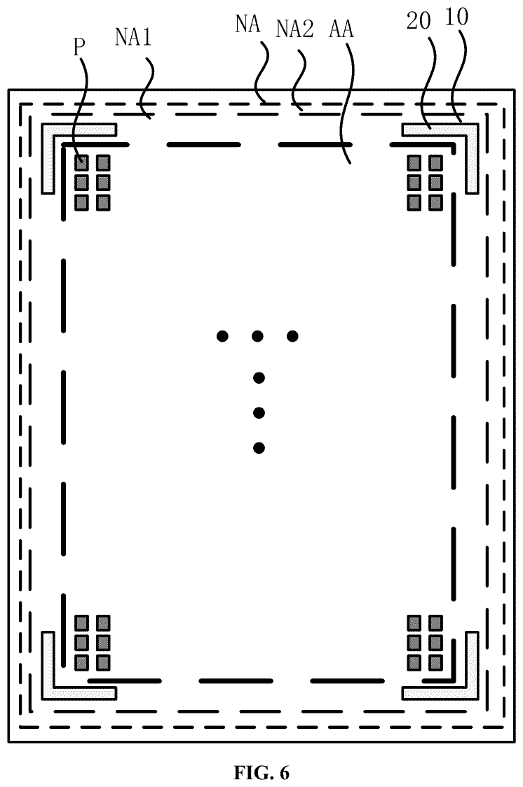

In one embodiment, there may be some areas with a larger width in the inorganic layer area NA1 in the non-display area NA, and there may be fewer or no vias in this area such that hydrogen elements may not be eliminated, resulting in more hydrogen elements gathering in these area, and hydrogen elements may move to the edge of the display area AA adjacent to them. As a result, hydrogen elements may move to the active layer of the transistor at the edge of the display area AA, and hydrogen may react with the active layer to degrade the electrical characteristics of the active layer, thereby affecting the characteristics of the transistor at the edge of the display area AA adjacent to it, resulting in the problem of a part of the edge of the display area AA of the display panel being bright. At this time, reference may be made to FIG. 6, which is a top view of another display panel provided by the present disclosure. A groove 10 may be provided in the wider area in the inorganic layer area NA1, which may alleviate the problem of the display panel having a partially bright edge in the display area AA, reduce the space occupied by the groove 10 in the non-display area NA, may be conducive to saving space for setting circuits, signal lines and other structures.

It should be noted that the structure diagram of the display panel shown in FIG. 6 may refer to FIG. 3-FIG. 5, and the present disclosure will not repeat the drawings, and the relevant structure diagrams may be applicable to other embodiments, and the present disclosure will not repeat them one by one.

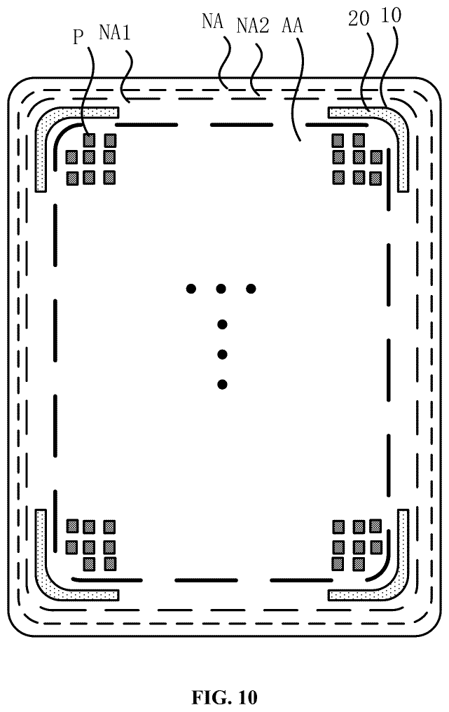

Further, referring to FIG. 6, in some embodiments, the groove 10 may be strip-shaped. Specifically, the structure diagram of the display panel shown in FIG. 6 may be referred to FIG. 3-FIG. 5. As shown in FIG. 10, when there is a part of the inorganic layer area NA1 in the non-display area NA with a large width, a stripe-shaped groove 10 may be set in the area such that the stripe-shaped groove 10 may effectively prevent hydrogen elements from moving to the active layer 41 of the transistor T in the corresponding display area AA, thereby effectively preventing hydrogen elements from reacting with the active layer 41 to degrade the electrical characteristics of the active layer 4. Accordingly, the stability of the characteristics of the transistor T at the edge of the corresponding display area AA may be effectively improved, and effectively alleviating the problem of the display panel having a part of the edge of the display area AA being bright.

At the same time, the groove 10 is stripe-shaped, which may effectively reduce the etching difficulty of the groove 10 in the inorganic layer area NA1 and effectively reduce the production cost.

Continuing to refer to FIG. 6, in some embodiments, the length of the groove 10 may be in a range of approximately 3-6 mm, and the width may be in a range of approximately 2-4 μm.

Specifically, when the length of the groove 10 is less than approximately 3 mm, the setting range of the groove 10 may be relatively small, the groove 10 may be unable to play a good barrier role for hydrogen elements, causing some hydrogen elements to move to the active layer 41 of the transistor T in the display area AA, and causing the display panel to still have the problem of partially bright edges in the display area AA. When the length of the groove 10 is greater than approximately 6 mm, the setting range of the groove 10 may be relatively large, resulting in a large setting area of the groove 10 in the non-display area NA, which may not be conducive to achieving a narrow frame. When the length of the groove 10 is a range of approximately 3-6 mm, while effectively alleviating the problem of partially bright edges in the display area AA of the display panel, it may be conducive to achieving a narrow frame.

When the width of the groove 10 is less than approximately 2 μm, that is, the width of the groove 10 is relatively small, the etching difficulty of the groove 10 may increase, increasing the production cost. When the width of the groove 10 is greater than approximately 4 μm, the setting range of the groove 10 may be relatively large, resulting in a large setting area of the groove 10 in the non-display area NA, which may not be conducive to achieving a narrow frame. When the width of the groove 10 is a range of approximately 2-4 μm, it may be conducive to achieving a narrow frame while effectively reducing the etching difficulty of the groove 10 and reducing the production cost.

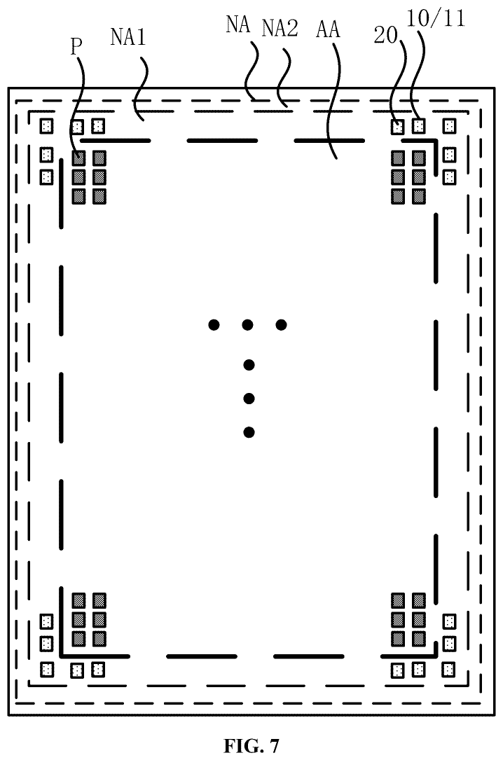

FIG. 7 is a planar schematic diagram of another exemplary display panel according to various disclosed embodiments of the present disclosure. The structural diagram of the display panel shown in FIG. 7 may be referred to FIG. 3-FIG. 5. As shown in FIG. 7, in some embodiments, the groove 10 may include a plurality of dot-shaped grooves 11.

Specifically, when the width of a portion of the inorganic layer area NA1 in the non-display area NA is relatively large, a plurality of dot-shaped grooves 11 may be set in the area such that the plurality of dot-shaped grooves 11 may effectively prevent hydrogen elements from moving to the active layer 41 of the transistor T in the corresponding display area AA, thereby effectively preventing hydrogen elements from reacting with the active layer 41 to degrade the electrical characteristics of the active layer 41. Accordingly, the stability of the characteristics of the transistor T at the edge of the corresponding display area AA may be effectively improved, and effectively alleviating the problem of the display panel having a portion of the edge of the display area AA being bright.

At the same time, the groove 10 may include a plurality of dot-shaped grooves 11, which may reduce the setting space occupied by the groove 10 in the non-display area NA, which may be conducive to saving space for setting circuits, signal lines and other structures.

Further, referring to FIG. 7, in some embodiments, the width of the dot-shaped groove 11 may be in a range of approximately 2-4 μm. Specifically, when the width of the dot-shaped groove 11 is less than 2 μm, that is, the width of the dot-shaped groove 11 may be relatively small, the etching difficulty of the dot-shaped groove 11 may increase, and the production cost may increase. When the width of the dot-shaped groove 11 is greater than 4 μm, the setting range of the dot-shaped groove 11 may be relatively large, resulting in a large setting area of the dot-shaped groove 11 in the non-display area NA, which may not be conducive to achieving a narrow frame. When the width of the dot-shaped groove 11 is a range of approximately 2-4 μm, while effectively reducing the etching difficulty of the dot-shaped groove 11 and reducing the production cost, it may be conducive to achieving a narrow frame.

Further, referring to FIG. 7, in some embodiments, the spacing of the dot-shaped grooves 11 may be in a range of approximately 1.5-3 μm. Specifically, when the spacing between adjacent dot-shaped grooves 11 is less than approximately 1.5 μm, the spacing between adjacent dot-shaped grooves 11 may be relatively small, which may increase the difficulty of etching the dot-shaped grooves 11 and increase the production cost. When the spacing between adjacent dot-shaped grooves 11 is greater than 3 μm, the spacing between adjacent dot-shaped grooves 11 may be relatively large, and the barrier effect on hydrogen elements may be poor, causing some hydrogen elements to be able to move to the active layer 41 of the transistor T in the display area AA, causing the display panel to still have the problem of partially bright edges of the display area AA. When the spacing between adjacent dot-shaped grooves 11 is a range of approximately 1.5-3 μm, while effectively reducing the difficulty of etching the dot-shaped grooves 11 and reducing the production cost, it may have a good barrier effect on hydrogen elements, effectively alleviating the problem of partially bright edges of the display area AA of the display panel.

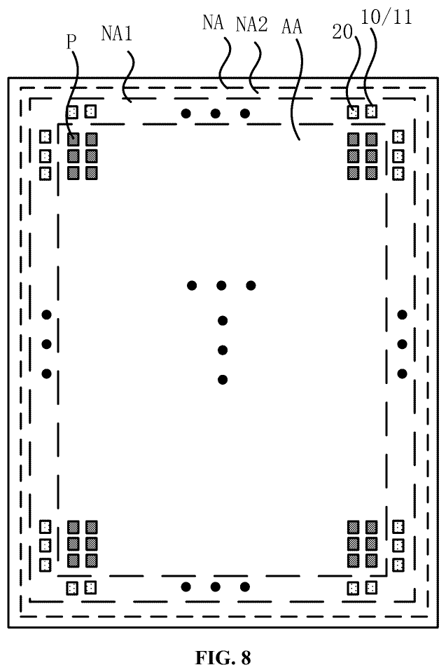

FIG. 8 is a top view of another exemplary display panel according to various disclosed embodiments of the present disclosure. The structure diagram of the display panel shown in FIG. 8 may be referred to FIG. 3-FIG. 5. As shown in FIG. 8, in some embodiments, the display area AA may include a plurality of sub-pixel units P, and the sub-pixel units P may include an oxide semiconductor layer. The dot-shaped grooves 11 may be arranged one-to-one with the sub-pixel units P at the edge of the display area AA.

Specifically, the display area AA may include a plurality of sub-pixel units P, and the sub-pixel units P may include an oxide semiconductor layer. In one embodiment, the active layer 41 of the transistor T in the sub-pixel unit P may be an oxide semiconductor layer, such as indium gallium zinc oxide (IGZO) as an active layer, to reduce the leakage current in the transistor T. However, in contrast, conventional oxide semiconductor layer is easy to react with hydrogen elements to degrade the electrical characteristics of the active layer, thereby resulting in poor stability of the transistor T.

The dot-shaped grooves 11 may be arranged one by one with the sub-pixel units P at the edge of the display area AA, that is, the sub-pixel units P at the edge of the display area AA may all be provided with dot-shaped grooves 11, and the dot-shaped grooves 11 may block the hydrogen elements, preventing the hydrogen elements from moving to the active layer 41 of the transistor T in the corresponding sub-pixel unit P, thereby effectively preventing the hydrogen elements from reacting with the active layer 41 and degrading the electrical characteristics of the active layer 41. Accordingly, the stability of the characteristics of the transistor T at the edge of the corresponding display area AA may be effectively improved, and effectively alleviating the problem of the display panel having a bright edge of the display area AA.

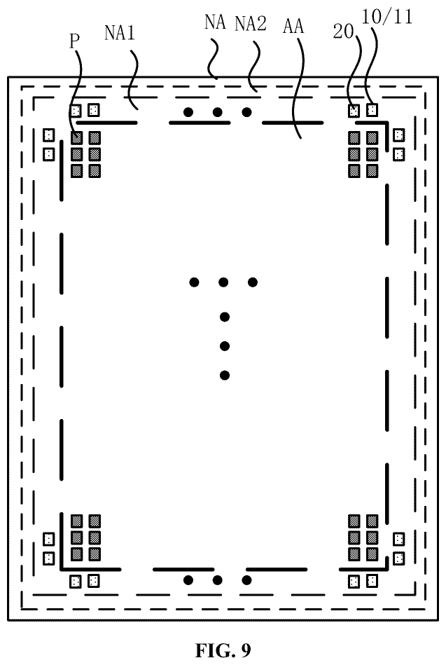

FIG. 9 is a top view of another exemplary display panel according to various disclosed embodiments of the present disclosure. The structure diagram of the display panel shown in FIG. 9 may be referred to FIG. 3-FIG. 5. As shown in FIG. 9, in one embodiment, when there is a portion of the inorganic layer area NA1 in the non-display area NA with a large width, a dot-shaped groove 11 may be set in the area such that the dot-shaped groove 11 may effectively prevent hydrogen elements from moving to the active layer 41 of the transistor T in the corresponding display area AA, thereby effectively preventing hydrogen elements from reacting with the active layer 41 to degrade the electrical characteristics of the active layer 41. Accordingly, the stability of the characteristics of the transistor T at the edge of the corresponding display area AA may be effectively improved, and effectively alleviating the problem of the display panel having a part of the edge of the display area AA being bright.

At the same time, the number of dot-shaped grooves 11 may be reduced, that is, the setting space occupied by the groove 10 in the non-display area NA may be reduced, which may be conducive to saving space for setting circuits, signal lines and other structures.

Further, referring to FIG. 2 and FIG. 3, in some embodiments, the non-display area NA may also include a driving circuit area NA2, the inorganic layer area NA1 may be located between the display area AA and the driving circuit area NA2, and the width of the inorganic layer area NA1 may be more than 200 μm. The minimum distance between the groove 10 and the display area AA may be in a range of approximately 0-120 μm.

Specifically, the non-display area NA may also include a driving circuit area NA2, and the driving circuit area NA2 may be provided with circuits and other structures, and the driving circuit area NA2 may be provided with a hole-like structure such as a via, and the hydrogen elements in the portion of the inorganic layer located in the driving circuit area NA2 may be discharged from the display panel through the hole-like structure. The inorganic layer area NA1 may be located between the display area AA and the driving circuit area NA2, and the width of the inorganic layer area NA1 may be more than 200 μm. The width of the inorganic layer area NA1 may be relatively large, and the portion of the inorganic layer located in the inorganic layer area NA1 may include more hydrogen elements.

The groove 10 may be arranged in the inorganic layer area NA; and the groove 10 may block the hydrogen elements in the inorganic layer located in the inorganic layer area NA1. At the same time, the filler 20 in the groove 10 may attract the hydrogen elements in the inorganic layer area NA1, which may be conducive to the discharge of hydrogen elements from the display panel through the filler 20.

The minimum distance between the groove 10 and the display area AA may be within 0-120 μm. The distance between the groove 10 and the display area AA may be relatively small, while preventing the hydrogen elements gathered in the inorganic layer area NA1 from entering the display area AA, it may be conducive to attracting the hydrogen elements at the edge of the display area AA, which may be conducive to the discharge of hydrogen elements from the display panel through the filler 20.

Further, referring to FIG. 2 and FIG. 3, in some embodiments, the depth of the groove 10 may be in a range of approximately 0.6 μm-1.6 μm. Specifically, when the depth of the groove 10 is less than 0.6 μm, the depth of the groove 10 may be relatively small, it may be unable to have a good barrier effect on the hydrogen element, causing a portion of the hydrogen elements to be able to move to the active layer 41 of the transistor T in the display area AA, causing the display panel to still have the problem of the edge of the display area AA being bright. When the depth of the groove 10 is greater than 1.6 μm, the depth of the groove 10 may be too large, it may be easy to etch the base substrate 51, affecting the overall performance of the display panel. When the depth of the groove 10 is in a range of approximately 0.6 μm-1.6 μm, while effectively alleviating the problem of the edge of the display area AA of the display panel being bright, it may not affect the overall performance of the display panel.

FIG. 10 is a planar schematic diagram of another exemplary display panel according to various disclosed embodiments of the present disclosure. The structural diagram of the display panel shown in FIG. 10 may be referred to FIGS. 3-5. As shown in FIG. 10, in some embodiments, the corners of the display area AA may be rounded, and the groove 10 may be arranged outside the rounded corners.

Specifically, the display panel provided in this embodiment may be a special-shaped display panel, and the corner of the display area AA may be a rounded structure. At this time, the width of the area corresponding to the rounded corner in the inorganic layer area NA1 in the non-display area NA may be relatively large, and there may be fewer or no vias in this area. Accordingly, the hydrogen element may not be eliminated, resulting in more hydrogen elements gathering in this area, and the hydrogen elements may move to the edge of the display area AA adjacent to it, and then the hydrogen elements may move to the active layer of the transistor at the edge of the display area AA. Hydrogen may react with the active layer to degrade the electrical characteristics of the active layer, thereby affecting the characteristics of the transistor at the edge of the display area AA adjacent to it, resulting in the display panel having the problem of the rounded edge of the display area AA being bright.

In one embodiment, the groove 10 may be set at the periphery of the rounded corner, for example, the groove 10 may be set in the area corresponding to the rounded corner in the inorganic layer area NA1, thereby alleviating the problem of the rounded edge of the display area AA being bright on the display panel. At the same time, the groove 10 may not be set in other areas, the setting space occupied by the groove 10 in the non-display area NA may be reduced, which may be conducive to saving space for setting circuits, signal lines and other structures.

It should be noted that this embodiment exemplarily shows that the groove 10 is set at the periphery of the rounded corner. In other embodiments of the present disclosure, when the width of other areas in the inorganic layer area NA1 is relatively large, the groove 10 may also be set, and the present disclosure will not be repeated here.

In one embodiment, a stripe-shaped groove 10 may be set at the periphery of the rounded corner, the stripe-shaped groove 10 may effectively prevent hydrogen elements from moving to the active layer 41 of the transistor T in the corresponding display area AA, thereby effectively preventing hydrogen elements from reacting with the active layer 41 to degrade the electrical characteristics of the active layer 41. Accordingly, the stability of the characteristics of the transistor T at the edge of the corresponding display area AA may be effectively improved, and effectively alleviating the problem of the display panel having a bright rounded edge of the display area AA.

At the same time, the groove 10 may be in a stripe shape, which may effectively reduce the etching difficulty of the groove 10 in the inorganic layer area NA1 and effectively reduce the production cost.

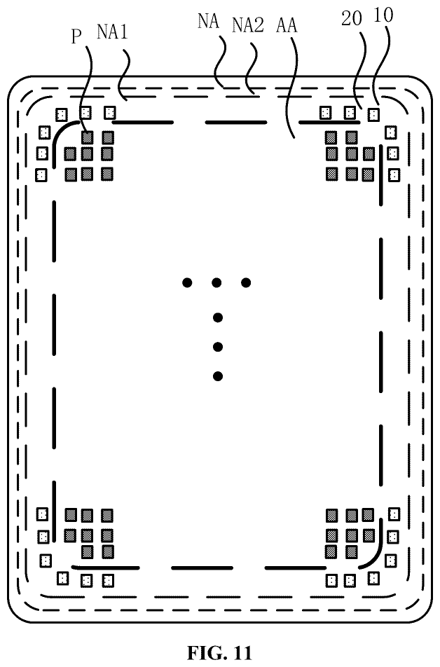

FIG. 11 is a top view of another exemplary display panel according to various disclosed embodiments of the present disclosure. The structure diagram of the display panel shown in FIG. 11 may be referred to FIG. 3-FIG. 5. As shown in FIG. 11, in some embodiments, a plurality of dot-shaped grooves 11 may be provided at the periphery of the rounded corner such that the plurality of dot-shaped grooves 11 may effectively prevent hydrogen elements from moving to the active layer 41 of the transistor T in the corresponding display area AA, thereby effectively preventing hydrogen elements from reacting with the active layer 41 to degrade the electrical characteristics of the active layer 41. Accordingly, the stability of the characteristics of the transistor T at the edge of the corresponding display area AA may be effectively improved, and effectively alleviating the problem of the display panel having a bright rounded corner edge of the display area AA.

At the same time, the groove 10 may include a plurality of dot-shaped grooves 11, which may reduce the setting space occupied by the groove 10 in the non-display area NA, which may be conducive to saving space for setting circuits, signal lines and other structures.

Further, referring to FIG. 10, in some embodiments, the groove 10 may extend along the arc of the rounded corner. Specifically, the groove 10 may extend along the arc of the rounded corner, that is, the groove 10 may be arranged around the rounded corner, and the groove 10 may play a good barrier role for the hydrogen elements gathered in the area corresponding to the rounder corner in the inorganic layer area NA1, effectively preventing the hydrogen elements from moving to the active layer 41 of the transistor T in the display area AA corresponding thereto, and thereby effectively preventing the hydrogen elements from reacting with the active layer 41 to degrade the electrical characteristics of the active layer 41. Accordingly, the stability of the characteristics of the transistor T at the edge of the display area AA corresponding thereto may be improved, and effectively alleviating the problem of the display panel having a bright edge of the rounded corner of the display area AA.

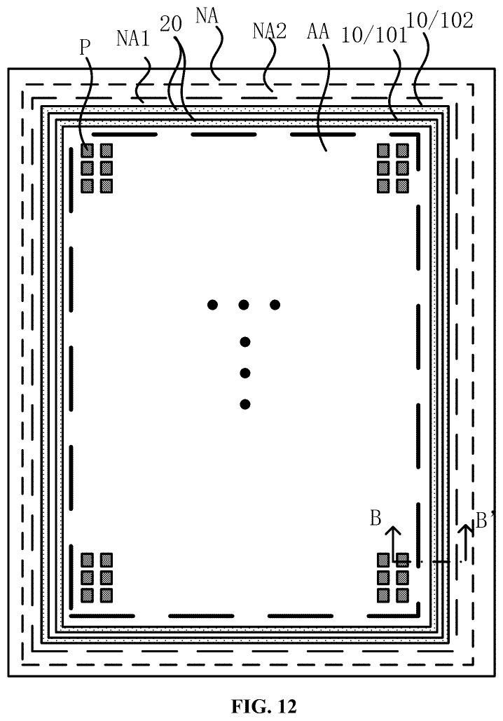

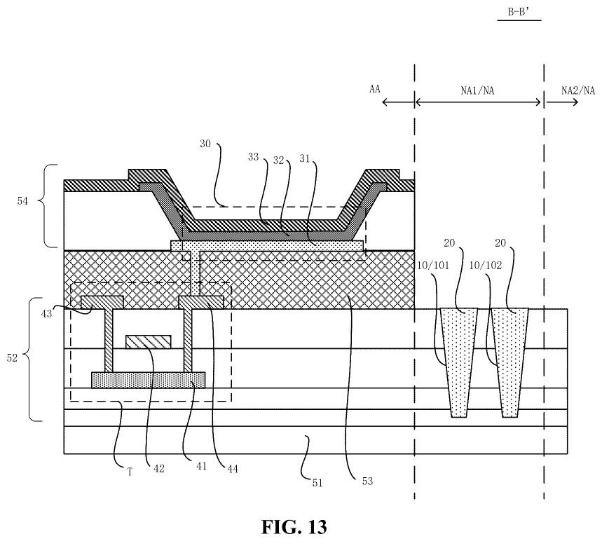

FIG. 12 is a top view of another exemplary display panel according to various disclosed embodiments of the present disclosure, and FIG. 13 is a cross-sectional view of the display panel along B-B′ described in FIG. 12. As shown in FIG. 12 and FIG. 13, in some embodiments, the groove 10 may include a first groove 101 and a second groove 102 arranged in parallel. The spacing between the first groove 101 and the display area AA may be smaller than the spacing between the second groove 102 and the display area AA.

Specifically, the groove 10 may include a first groove 101 and a second groove 102 arranged in parallel, the first groove 101 and the second groove 102 may effectively block the hydrogen element in the inorganic layer area NA1 from moving to the display area AA, thereby preventing the hydrogen element from moving to the active layer 41 of the transistor T in the display area AA, and thereby effectively preventing the hydrogen element from reacting with the active layer 41 to degrade the electrical characteristics of the active layer 41. Accordingly, the stability of the characteristics of the transistor T at the edge of the display area AA may be effectively improved, and further alleviating the problem of the display panel having a bright edge of the display area AA.

At the same time, fillers 20 may be formed in both the first groove 101 and the second groove 102. The material of the fillers 20 may be a material that has an attracting effect on hydrogen elements such that the filler 20 may attract hydrogen elements in the inorganic layer area NA1, which may be conducive to the discharge of hydrogen elements from the display panel through the fillers 20, effectively reducing the hydrogen elements in the inorganic layer area NA1, thereby effectively preventing hydrogen elements from moving to the active layer 41 of the transistor T in the display area AA, and thereby effectively preventing hydrogen elements from reacting with the active layer 41 to degrade the electrical characteristics of the active layer 41. Accordingly, the stability of the characteristics of the transistor T at the edge of the display area AA may be effectively improved, and further alleviating the problem of the display panel having a bright edge of the display area AA.

It should be noted that this embodiment exemplarily shows that the groove 10 may include a first groove 101 and a second groove 102 arranged in parallel. In other embodiments of the present disclosure, three or more grooves 10 arranged in parallel may also be included to improve the barrier effect on hydrogen elements. The present disclosure will not repeat one by one.

Further, referring to FIG. 12 and FIG. 13, in some embodiments, the minimum distance between the first groove 101 and the display area AA may be within 0-120 μm. The non-display area NA may also include the driving circuit area NA2, the inorganic layer area NA1 may be located between the display area AA and the driving circuit area NA2, and the minimum distance between the second groove 102 and the driving circuit area NA2 may be within 0-120 μm.

Specifically, the minimum distance between the first groove 101 and the display area AA may be within 0-120 μm, that is, the distance between the first groove 101 and the display area AA may be relatively small, while preventing the hydrogen elements gathered in the inorganic layer area NA1 from entering the display area AA, it may be beneficial to attract the hydrogen elements at the edge of the display area AA, and thereby facilitating the hydrogen elements to be discharged from the display panel through the filler 20.

The minimum distance between the second groove 102 and the driving circuit area NA2 may be within 0-120 μm. The filler 20 provided in the first groove 101 and the second groove 102 may uniformly attract the hydrogen elements in the inorganic layer area NA1, which may be conducive to the discharge of hydrogen elements in various areas of the inorganic layer area NA1 from the display panel.

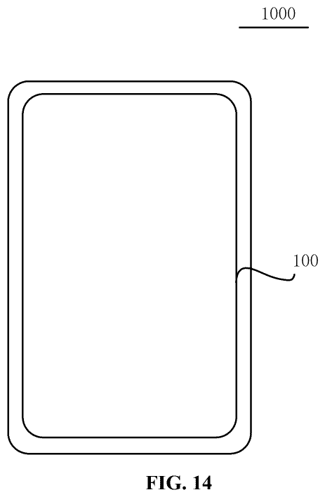

The present disclosure also provides a display device. FIG. 14 is a planar schematic diagram of an exemplary display device according to various disclosed embodiments of the present disclosure. As shown in FIG. 14, the present disclosed display device 1000 may include a display panel 100 provided by any of the above embodiments, or other appropriate display panel. The embodiment provided in FIG. 14 only takes a mobile phone as an example to illustrate the display device. It can be understood that the display device provided by the embodiment of the present disclosure may be any electronic product with a display function, including but not limited to the following categories: mobile phones, televisions, notebook computers, desktop displays, tablet computers, digital cameras, smart bracelets, smart glasses, car displays, medical equipment, industrial control equipment, touch interactive terminals, etc., and the embodiment of the present disclosure does not specifically limit this.

The display device 1000 provided by the disclosed embodiment of the present disclosure may include the same technical features as the display panel 100 provided by the above embodiments, thus it may also solve the same technical problems and achieve the same technical effects.

The technical solution disclosed in the present disclosure may include the following advantages. In the display panel disclosed in the present disclosure, the inorganic layer area may be adjacent to the display area, and a groove may be formed in the inorganic layer area. The setting of the groove may effectively block the hydrogen element in the inorganic layer area from moving to the display area, thereby preventing the hydrogen element from moving to the active layer of the transistor in the display area, thereby effectively preventing the hydrogen element from reacting with the active layer to degrade the electrical characteristics of the active layer. Accordingly, the stability of the characteristics of the transistor at the edge of the display region may be effectively improved, and effectively alleviating the problem of the display panel having a bright edge in the display region. Further, a filler may be formed in the groove, and the material of the filler may be a material that has an attracting effect on the hydrogen element such that the filler may attract the hydrogen element in the inorganic layer area, thereby facilitating the hydrogen element to be discharged from the display panel through the filler, effectively reducing the hydrogen element in the inorganic layer region, thereby effectively preventing the hydrogen element from moving to the active layer of the transistor in the display region, and thereby effectively preventing the hydrogen element from reacting with the active layer to degrade the electrical characteristics of the active layer. Accordingly, the stability of the characteristics of the transistor at the edge of the display region may be improved; and further alleviating the problem of the display panel having a bright edge in the display region.

It should be noted that, in the present disclosure, relational terms such as “first” and “second” are only used to distinguish one entity or operation from another entity or operation, and do not necessarily require or imply any such actual relationship or order between these entities or operations. Moreover, the terms “include”, “comprise” or any other variants thereof are intended to cover non-exclusive inclusion such that a process, method, article or device including a series of elements includes not only those elements, but also other elements not explicitly listed, or also includes elements inherent to such process, method, article or device. In the absence of further restrictions, the elements defined by the sentence “including one . . . ” do not exclude the existence of other identical elements in the process, method, article or device including the elements.

The above description is only a specific embodiment of the present disclosure, such that those skilled in the art of the present disclosure can understand or implement the present disclosure. Various modifications to these embodiments will be obvious to those skilled in the art of the present disclosure, and the general principles defined in the present disclosure can be implemented in other embodiments without departing from the spirit or scope of the present disclosure. Therefore, the present disclosure will not be limited to the embodiments described in the present disclosure, but will conform to the widest scope consistent with the principles and novel features disclosed in the present disclosure.

What is claimed is:

1. A display panel, comprising:
a display area; and
a non-display area,
wherein:
the non-display area includes an inorganic layer area;
the inorganic layer area is adjacent to the display area;
the inorganic layer area is formed with a groove; and
a filler is formed in the groove.

2. The display panel according to claim 1, wherein:
the filler includes one of a metal film layer and an organic film layer.

3. The display panel according to claim 1, wherein:
the groove is stripe-shaped.

4. The display panel according to claim 3, wherein:
a length of the groove is in a range of approximately 3 mm-6 mm; and
a width of the groove is in a range of approximately 2 μm-4 μm.

5. The display panel according to claim 1, wherein the groove comprises:
a plurality of dot-shaped grooves.

6. The display panel according to claim 5, wherein:
a width of a dot-shaped groove of the plurality of dot-shaped grooves is in a range of approximately 2 μm-4 μm.

7. The display panel according to claim 5, wherein:
a spacing of two adjacent dot-shaped grooves of the plurality of dot-shaped grooves is in a range of approximately 1.5 μm-3 μm.

8. The display panel according to claim 5, wherein the display area comprises:
a plurality of sub-pixel units, wherein a sub-pixel unit of the plurality of sub-pixel units includes an oxide semiconductor layer, and the plurality of dot-shaped grooves are arranged in one-to-one correspondence with sub-pixel units of the plurality of sub-pixel units at an edge of the display area.

9. The display panel according to claim 1, wherein the non-display area comprises:
a driving circuit area, wherein the inorganic layer area is located between the display area and the driving circuit area, a width of the inorganic layer area is more than 200 μm, and a minimum distance between the groove and the display area is within 0-120 μm.

10. The display panel according to claim 1, wherein:
a depth of the groove is in a range of approximately 0.6 μm-1.6 μm.

11. The display panel according to claim 1, wherein:
a corner of the display area is a rounded corner; and
the groove is disposed in a peripheral area of the rounded corner.

12. The display panel according to claim 11, wherein:
the groove extends along an arc of the rounded corner.

13. The display panel according to claim 1, wherein the groove comprises:
a first groove and a second groove disposed in parallel; and
a spacing between the first groove and the display area is smaller than a spacing between the second groove and the display area.

14. The display panel according to claim 13, wherein:
a minimum distance between the first groove and the display area is within 0-120 μm;
the non-display area also includes a driving circuit area;
the inorganic layer area is located between the display area and the driving circuit area; and
a minimum distance between the second groove and the driving circuit area is within 0-120 μm.

15. A display device, comprising:
a display panel including a display area and a non-display area,
wherein:
the non-display area includes an inorganic layer area;
the inorganic layer area is adjacent to the display area;
the inorganic layer area is formed with a groove; and
a filler is formed in the groove.
